(19) United States
(12) Patent Application Publication
(10) Pub. No.: US 2011/0198401 A1
(43) Pub. Date: Aug. 18, 2011

(54) Wireless antenna for RFID for tires

(75) Inventor: Randall L. Tucker, Findlay, OH (US)

(73) Assignee: Cooper Tire & Rubber Company

(21) Appl. No.: 12/806,726

(22) Filed: Aug. 18, 2010

Related U.S. Application Data
(60) Provisional application No. 61/337,933, filed on Feb. 12, 2010.

(51) Int. Cl. G06K 19/077; H05K 13/00

(52) U.S. Cl. 235/492; 29/592.1

(57) ABSTRACT

An RFID device for tires utilizes a wireless antenna. The antenna is formed of conductive rubber having a slot formed therein. The conductive rubber antenna is encapsulated between a pair of non-conductive sheets. A third non-conductive member encircles the conductive rubber antenna and is itself sealed between the first and second sheets of non-conductive material. A microchip is positioned in the slot and conductively attached to the antenna on opposite sides of the slot.

### CROSS REFERENCE TO RELATED APPLICATION

This application is based upon and claims the benefit of U.S. Provisional Patent Application No. 61/337,933 filed Feb. 12, 2010.

### BACKGROUND OF THE INVENTION

The use of radio frequency identification devices (RFID) in tires is gaining in popularity. See for example my issued U.S. Pat. No. 7,504,947. Other devices, including RFID devices, which may be incorporated on a surface of or within the structure of a tire for monitoring various functions relative to the tire include the following U.S. Pat. Nos. 5,562,787; 5,741,966; 6,062,072; 6,856,245; 6,897,770; 7,009,576; and 7,186,308. The disclosures contained in these patents are incorporated herein by reference.

U.S. Pat. No. 7,009,576 discloses a tire having a radio frequency antenna embedded therein. Since the rubber in which the radio frequency antenna is embedded is in a mixture of rubber and the conductive dielectric material carbon black, the patent discloses the use of an insulating layer, which is attached to the antenna by an adhesive coating, to insulate the antenna from the conductive dielectric rubber. Although U.S. Pat. No. 7,009,576 does not specifically identify the material from which the antenna is manufactured, typically, the antenna will be a conductive metal wire or a thin sheet of metal foil such as copper as disclosed in U.S. Pat. No. 5,562,787 or 6,147,659.

RFID devices for use in tires continues to be a goal in order to provide improved quality and traceability. However, the tire industry has been slow to adopt the RFID devices with their copper antennas. The installation foreign material in a tire is a concern. The ability to provide RFID devices in a tire with minimal component size is an important goal.

### SUMMARY OF THE PRESENT INVENTION

The RFID device of the present invention utilizes a wireless antenna of conductive rubber along with a computer chip and is embedded in the body of a tire or affixed to the inner surface of the tire. The antenna is formed of electrically conductive green rubber encapsulated in insulation formed by a pair of non-conducting green rubber sheets adhered together. The insulation preferably is a non-conducting green rubber but could be non-conducting rubber or other materials having properties suitable for integration within the rubber tire. Other materials which may be utilized for the insulation include an elastomer or rubber minus the carbon black which is the conductive component. The insulation isolates the antenna from the dielectric rubber of the tire and, thereby, prevents the conductive rubber from dissipating the energy being conducted by the antenna.

The RFID device of the present invention utilizes a standard computer chip, preferably an EPC1 GEN2 RFID chip of less than one millimeter (1 mm)×one millimeter in size. The RFID chip is coupled with a conductive rubber dipole or slot antenna. Under one embodiment, conductive adhesives and/or other encapsulates maybe utilized to improve the interface between the chip mounting and the rubber antenna thus improving the performance. In this case, cured or vulcanized rubber rather than green rubber could be used for the antenna. If green rubber is used for the antenna, it is not necessary to use adhesive as the natural stickiness of the green rubber will cause it to adhere to the surface of the insulating layer engaged thereto. On the other hand, it is possible to use adhesive with an antenna of green rubber in order to provide a more effective seal. The sub-assembly of the rubber antenna and the computer chip is enclosed in a non-conductive rubber envelope or sheets. The current technology allows for the rubber antenna to be an integral component of the tire with no concerns of destroying the integrity of the tire.

Preferably the RFID device of the present invention is produced in the uncured state. It is affixed to the inner or outer surface of the tire in the green state. It may also be embedded in the tires, between the plies. Following such affixing or embedding, it is vulcanized along with the rest of the tire. However, it could also be vulcanized and then affixed following vulcanization of the tire or assembled using vulcanized conductive rubber and then affixed to the tire. The installed RFID devices will allow improved quality, sorting of tires on conveyors and tracking of shipments.

The prior art RFID devices for tires utilize a wire wound antenna. The wire wound antenna comes into direct contact with the rubber. The carbon black used in the tire rubber causes the rubber to be somewhat conductive. Unless properly insulated, the conductive characteristics of the tire rubber will de-tune the antenna of the RFID device which greatly reduces its effective range.

The antenna of the RFID device of the present invention has a conductive rubber compound which has been developed for its conductivity to get into the range of 20 ohms to 400 ohms per inch of rubber. Resistances in the range of 40-100 ohms per inch are suitable for use as an antenna. The non-conductive rubber is utilized as an electrical insulator which isolates the antenna from the rubber of the tire. The encapsulation in the non-conductive rubber causes the antenna to stay in tune with the RFID microchip, which allows for the long range read characteristics.

### IN THE DRAWINGS

FIG. 1 is a sectional view of a tire showing an RFID device with the antenna of the present invention encapsulated therein or affixed to the interior sidewall.

FIG. 2 is a plan view showing one form of RFID device with a microchip and antenna encapsulated in and between layers of insulation material.

FIG. 3 is a sectional view along line 3-3 of FIG. 2.

FIG. 4 is an exploded perspective view of the RFID device of the present invention utilizing the wireless antenna of the present invention.

### DETAILED DESCRIPTION OF THE INVENTION

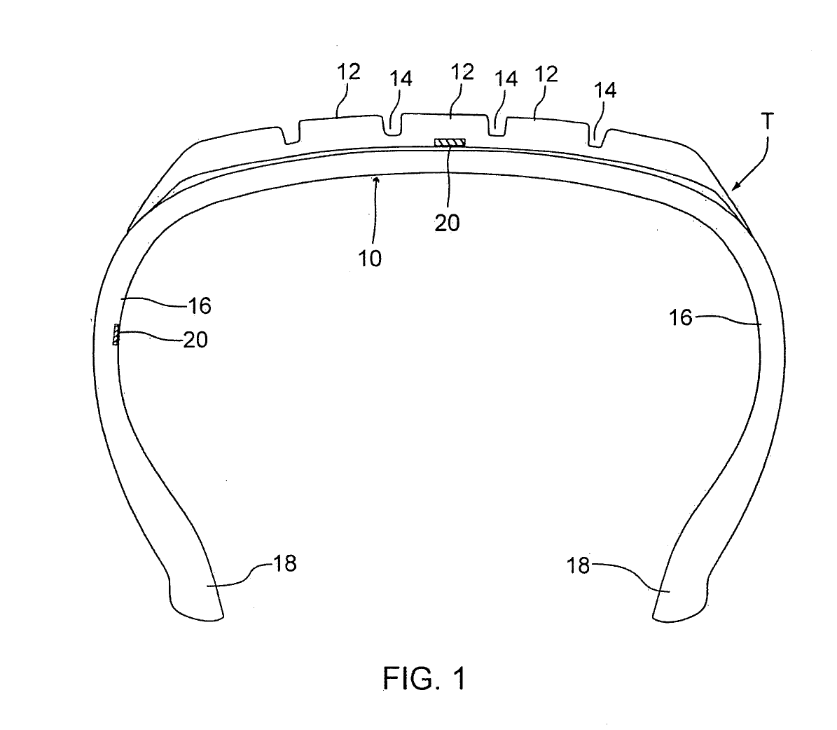

Referring to FIG. 1 there is shown a tire T having a crown 10 with external treads 12 and grooves 14. In cross-section the tire T has the crown 10 extending radially outwardly along an arcuate path to a pair of oppositely disposed sidewalls 16 which define the maximum radial extent of the tire T. The sidewalls 16 curve inwardly from such maximum radial extent to a narrower area terminating at a pair of oppositely disposed beads 18. As shown in FIG. 1 there is provided an RFID device 20 of the present invention which is permanently embedded either in the crown 10 or in one of the sidewalls 16. It may also be adhered to the inner surface of the tire in the area of the crown 10 or the sidewall 16.

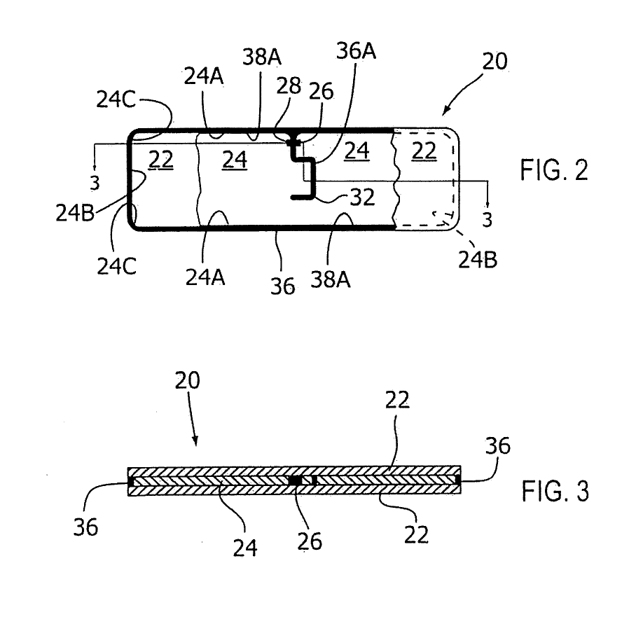

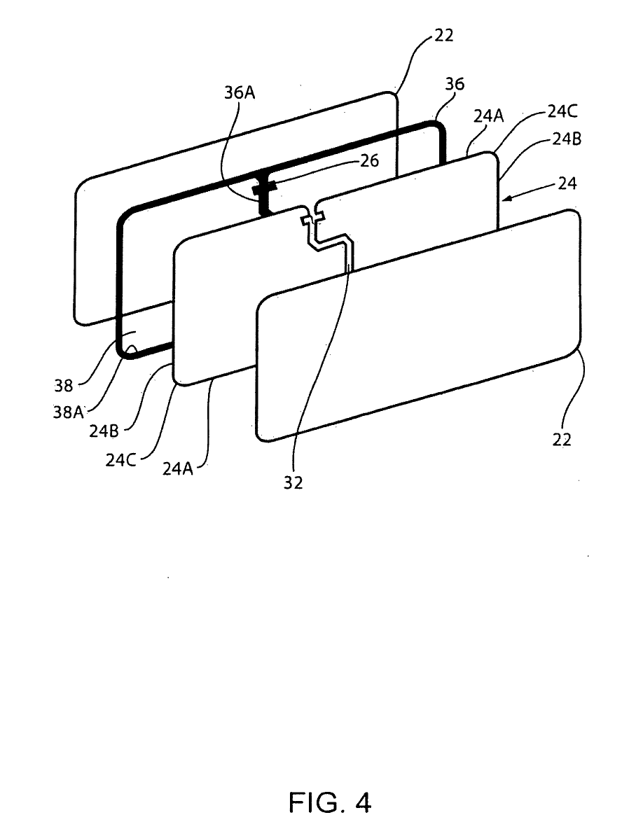

Referring to FIGS. 2, 3 and 4, the RFID device includes a pair of insulation members 22 and an antenna 24 encapsulated therebetween. A RFID microchip 26 such as EPC1 GEN has tabs 28 attached to the antenna 24. The antenna 24, which may be one of a number of shapes, is shown as a rectangle having a length defined by long upper and lower (as viewed in FIGS. 2 and 4) edges 24A, short side edges 24B and curved or arcuate corners 24C.

The antenna 24 has a slot 32 extending downwardly (as viewed in FIGS. 2 and 4) from the upper edge 24A which follows a path which provides suitable tuning characteristics for the specific RFID microchip 26 utilized.

The slot 32 as shown in FIG. 2 follows a downward path toward the lower edge 24A followed by one curving into a perpendicular segment extending toward the side edge 24B on the right followed by another segment extending toward the lower edge 24A and finally one extending toward the side edge 24B on the left. The slot 32 could also have segments disposed at acute angles to the edges 24A and 24B as well as curved segments depending on the shape most suitable for tuning for the specific RFID microchip utilized. Depending upon the characteristics of the microchip, it could also be straight and could extend completely between the upper edge 24A and the lower edge 24A thereby resulting in the antenna 24 being two pieces separated by the slot 32.

As may be seen most clearly in FIGS. 2 and 4, a stamped or otherwise shaped central insulation member 36 formed of non-conductive green rubber is also positioned between the two insulation members 22. The stamped insulation member 36 has an enlarged opening 38 sized to snugly receive therein the antenna 24. Thus, the internal edge 38A of the opening 38 is substantially the same size as the peripheral edge of the antenna 24 as represented by the numerals 24A, 24B, and 24C. With this construction, the antenna 24, including its edges is completely encapsulated in non-conducting insulation members 22, 36 and 22.

The stamped insulation member 36 has an internal extension 36A sized and shaped to fit in the slot 32. The internal extension 36A substantially fills the slot 32. If the slot 32 was not filled with the insulation of the internal extension 36A, the green rubber of the antenna 24 would flow into the slot 32 during vulcanization of the tire or during vulcanization of the RFID device 20 if done prior to its assembly in the tire T.

As previously discussed, the length and shape of the slot 32 are designed to tune the antenna to be at substantially the same frequency of the RFID microchip 26.

In preparation for assembly of the insulation members 22, the antenna 24 and the stamped insulation member 36, the RFID microchip 26 may be mounted on either the stamped insulation member 36 (as shown in FIG. 4) or on the antenna 24. In either event, the tabs 28 of the microchip must be engaged to the antenna 24 on opposite sides of the slot 32 when the components are assembled to form the RFID device 20. The location of the chip may be adjusted to improve performance of the RFID device 20.

The insulation members 22 may be formed of any of a number of non-conductive or low conductive materials such as those specified above and having a dielectric constant of about 4 or less. The insulation members 22 have a thickness in the range of 0.05 mm to 3 mm, where mm is millimeters. The thickness of the antenna 24 and the central insulation member 36 are also in the range of 0.05 mm to 3 mm. Although the central insulation member 36 and the antenna 24 should be the same thickness, it is not necessary that they be the same thickness as the other insulation members 22, 22. They could be thinner or thicker than such other insulation members 22, 22. Additionally, it is possible that one on the outer insulation members 22 be thicker than the other outer insulation member 22.

The amount of carbon black and/or other ingredients providing conductivity to the antenna 24 is such as to give it a resistance in the range of 20 ohms to 400 ohms and preferably in the range of 40 ohms to 100 ohms.

As can be seen in FIG. 3, the opposing insulation members 22, 22 are sealed to the central insulation member 36 completely around the periphery to thereby encapsulate the antenna 24 and the RFID chip 26. As previously discussed, the internal edge 38A of the enlarged opening 38 seals the edges 24A, 24B and 24C of the antenna 24. Preferably, the insulation members 22, 22 and 36 are formed non-conductive green (non-vulcanized) rubber. When manufactured of green rubber, the edges of the opposed insulation members 22 will adhere to the central insulation member 36 without the necessity of providing any adhesive therebetween. The insulation members 22, 36, 22 will also adhere to the antenna 24 without the use of adhesive provided all of such members are green rubber. When green rubber is used for the insulation and the antenna 24, the insulation members 22, 22 and the central insulation member 36 can be sealed together and to the antenna 24 simply by pressing together. If the insulation members 22 and/or central insulation member 36 and/or antenna 24 are formed of a material other than green rubber, they can be heat sealed or adhesively joined together.

The completed assembly of the insulation members 22, 22 central insulation member 36, antenna 24 and RFID microchip 26 forming the RFID device 20 may be positioned in the tire T between the various plies thereof or on its inner surface as previously discussed. Following positioning in the tire T or in its inner surface, it will be included in the vulcanization of the tire thereby providing a completed tire and RFID device with a wireless antenna.

If desired, the RFID device of the present invention could be packaged while the insulation layers 22, 22 and 36 and the antenna 24 layer are in the green state and then shipped another manufacturing facility for installation in tires during manufacturing. Additionally, the RFID device of the present invention could itself be vulcanized prior to incorporation in a tire.

The RFID device of the present invention is one which is economical to manufacture and can be provided with a configuration to provide one of a number of levels of resistance tailored to the specific requirements of the device.

Many modifications will be readily apparent to those skilled in the art. Accordingly, the scope of the present invention should be determined by the scope of the claims appended hereto.

1. An RFID device comprising
(a) an antenna of a sheet of electrically conducting rubber, said sheet having an elongated slot;
(b) a microchip positioned in said slot and connected to said sheet at a first location on one side of said slot and at a second location on the opposing side of said slot; and
(c) non-conductive material encapsulating said antenna and said microchip.

2. The RFID device according to claim 1 wherein said non-conductive encapsulating material includes a first sheet adhered to one side of said antenna, a second sheet adhered to a second side of said antenna and a non-conductive shaped member encircling said antenna and adhered to said first and second sheets.

3. The RFID device according to claim 2 wherein said shaped member includes an extension positioned in said slot.

4. The RFID device according to claim 1 wherein said antenna sheet has a peripheral edge and said non-conductive material includes (i) a shaped non-conductive member encircling said peripheral edge; (ii) a first sheet of non-conductive material adhered to one side of said antenna sheet and (iii) a second sheet of non-conductive material adhered to the opposing side of said antenna sheet.

5. The RFID device according to claim 1 wherein said antenna has an electrical resistance in the range of 20 ohms to 400 ohms.

6. The RFID device according to claim 1 wherein said antenna has an electrical resistance in the range of 40 ohms to 100 ohms.

7. The RFID device according to claim 1 wherein each of said antenna and said non-conductive material has a thickness in the range of 0.05 mm to 3 mm.

8. The RFID device according to claim 4 wherein each said antenna, said shaped non-conductive member and said first and second sheets of non-conductive material have a thickness in the range of 0.05 mm to 3 mm.

9. The RFID device according to claim 4 wherein the adherence of said first and second sheets to said antenna results from said antenna or said first and second sheets being green rubber.

10. An RFID device comprising:
(a) a first sheet of non-conductive material having an outwardly facing peripheral edge;
(b) an antenna of conductive rubber engaged to said first sheet and having an outwardly facing peripheral edge spaced inwardly from said first sheet peripheral edge, said antenna having a slot therein, said slot following a straight or non-straight path;
(c) a microchip positioned in said slot and conductively engaged to antenna at least two points, one of said points located on one side of said slot and the other of said points located on the other side of said slot;
(d) a non-conductive member encircling said antenna and engaging said outwardly facing peripheral edge of said antenna, said non-conductive member having an internal extension positioned in said slot; and
(e) a second sheet of non-conductive material engaged to (i) said antenna and (ii) said encircling non-conductive member.

11. The RFID device according to claim 10 wherein said antenna has an electrical resistance in the range of 20 ohms to 400 ohms.

12. The RFID device according to claim 10 wherein said antenna has an electrical resistance in the range of 40 ohms to 100 ohms.

13. The RFID device according to claim 10 wherein each of said antenna and said encircling non-conductive member has a thickness in the range of 0.05 mm to 3 mm.

14. The RFID device according to claim 10 wherein said first and second sheets are adhered to said antenna by said antenna or said first and second sheets being green rubber.

15. A tire having implanted therein or fastened on a surface thereof the RFID device of claim 10.

16. A method for forming an RFID device comprising the steps of:
(a) providing a sheet of electrically conductive rubber having a peripheral edge;
(b) forming a slot in said conductive sheet;
(c) encircling said peripheral edge with non-conductive material;
(d) positioning a microchip in said slot;
(e) electronically connecting said microchip to said conductive sheet on opposite sides of said slot; and
(f) fastening non-conductive material to opposite sides of said conductive sheet and to said encircling non-conductive material.

17. The method according to claim 15 wherein said electrically conductive rubber is in the green state throughout steps (a) through (f) and further including the step of vulcanizing the assembly formed by steps (a) through (f).

18. The method according to claim 16 further including the step of positioning non-conductive material in those portions of said slot not occupied by said microchip.

19. The method according to claim 16 wherein said electrically conductive rubber is in the green state throughout steps (a) through (f) and further including the step of engaging said RFID device with said electrically conductive rubber in the green state to a partially manufactured tire having components of rubber in the green state and thereafter vulcanizing said tire and said RFID device.

20. A method for forming an RFID device comprising the steps of:
(a) providing an antenna of electrically conductive rubber having a peripheral edge and a thickness in the range of 0.05 mm to 3 mm;
(b) forming a slot in said antenna;
(c) encircling said peripheral edge with non-conductive material having the same thickness as said antenna;
(d) positioning a microchip in said slot;
(e) electrically connecting said microchip to said antenna on opposite sides of said slot; and
(f) fastening non-conductive material having a thickness in the range of 0.05 mm to 3 mm to opposite sides of said antenna and to said encircling non-conductive material.

21. The method according to claim 20 wherein said electrically conductive rubber is in the green state throughout steps (a) through (f) and further including the step of vulcanizing the assembly formed by steps (a) through (f).

22. The method according to claim 20 further including the step of positioning non-conductive material in those portions of said slot not occupied by said microchip.

23. The method according to claim 20 wherein said antenna has an electrical resistance in the range of 20 ohms to 400 ohms.

24. The method according to claim 20 wherein said electrically conductive rubber is in the green state throughout steps (a) through (f) and further including the step of engaging said RFID device with the electrically conductive rubber of said antenna being in the green state to a partially manufactured tire having components of rubber in the green state and thereafter vulcanizing said tire and said RFID device.
